(19) United States
(12) Patent Application Publication
(10) Pub. No.: US 2023/0197607 A1
(43) Pub. Date: Jun. 22, 2023

(54) LINE FORMATION WITH SMALL TIP SPACING

(71) Applicant: INTERNATIONAL BUSINESS MACHINES CORPORATION, Armonk, NY (US)

(72) Inventors: Ruilong Xie, Niskayuna, NY (US); Heng Wu, Guilderland, NY (US); Julien Frougier, Albany, NY (US); Min Gyu Sung, Latham, NY (US)

(21) Appl. No.: 17/554,799

(22) Filed: Dec. 17, 2021

(51) Int. Cl. H01L 23/528; H01L 23/522; H01L 21/768

(52) U.S. Cl. CPC H01L 23/528; H01L 21/76802; H01L 21/76879; H01L 23/5226

(57) ABSTRACT

Semiconductor devices and methods of forming the same include forming a multilayer dielectric structure, including a first dielectric layer and a second dielectric layer, between dielectric lines. Exposed portions of the first dielectric layer are etched away, leaving remnants between the second dielectric layer and the dielectric lines, to decrease a width of the multilayer dielectric structure. Conductive lines are formed between the dielectric lines, on respective sides of the multilayer dielectric structure.

### BACKGROUND

The present invention generally relates to semiconductor device fabrication, and, more particularly, to the formation of interconnects.

As fabrication technologies improve, and device pitch continues to scale down, decreasing the tip-to-tip spacing between interconnects becomes challenging. Tip-to-tip spacing in devices that are formed using subtractive processes may be limited by the minimum feature size of a fabrication technology that is being used.

### SUMMARY

A method of forming lines includes forming the same include forming a multilayer dielectric structure, including a first dielectric layer and a second dielectric layer, between dielectric lines. Exposed portions of the first dielectric layer are etched away, leaving remnants between the second dielectric layer and the dielectric lines, to decrease a width of the multilayer dielectric structure. Conductive lines are formed between the dielectric lines, on respective sides of the multilayer dielectric structure.

A method of forming lines includes patterning a conductive layer to form a conductive line on an underlying substrate. A cut region is etched into the conductive line to expose a surface of the underlying substrate and to cut the conductive line into respective interconnects. Additional conductive material is selectively deposited on sidewalls of the cut region to decrease a width of the cut region. A dielectric plug is formed in the cut region.

A semiconductor device may include a pair of conductive interconnects, arranged end-to-end. At least one conductive interconnect is parallel to the pair of conductive interconnects, with a feature pitch separating the at least one conductive interconnect from the pair of conductive interconnects that is associated with a fabrication process. A dielectric structure is between the pair of conductive interconnects, having a width that is smaller than the feature pitch.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a top-down view of a set of conductive lines in a semiconductor device, with at least one of the conductive lines being broken by a cut structure that separates the line into distinct interconnects, in accordance with an embodiment of the present invention;

FIG. 2 is a set of cross-sectional views that show a step of a first embodiment of the fabrication of metal lines with a small tip-to-top spacing, where trench lines are formed on a substrate, in accordance with an embodiment of the present invention;

FIG. 3 is a set of cross-sectional views that show a step of a first embodiment of the fabrication of metal lines with a small tip-to-top spacing, where sacrificial material is formed in the trenches outside of a cut region, in accordance with an embodiment of the present invention;

FIG. 4 is a set of cross-sectional views that show a step of a first embodiment of the fabrication of metal lines with a small tip-to-top spacing, where a multilayer dielectric structure is formed in the cut region, in accordance with an embodiment of the present invention;

FIG. 5 is a set of cross-sectional views that show a step of a first embodiment of the fabrication of metal lines with a small tip-to-top spacing, where the sacrificial material is removed, in accordance with an embodiment of the present invention;

FIG. 6 is a set of cross-sectional views that show a step of a first embodiment of the fabrication of metal lines with a small tip-to-top spacing, where one layer of the multilayer dielectric structure is etched to narrow the cut in one direction, in accordance with an embodiment of the present invention;

FIG. 7 is a set of cross-sectional views that show a step of a first embodiment of the fabrication of metal lines with a small tip-to-top spacing, where metal lines are formed in the trenches, around the multilayer dielectric structure, in accordance with an embodiment of the present invention;

FIG. 8 is a set of cross-sectional views that show a step of a second embodiment of the fabrication of metal lines with a small tip-to-top spacing, where a layer of conductive material is deposited on a substrate using an adhesion layer, in accordance with an embodiment of the present invention;

FIG. 9 is a set of cross-sectional views that show a step of a second embodiment of the fabrication of metal lines with a small tip-to-top spacing, the layer of conductive material and the adhesion layer are patterned to form lines and vias, in accordance with an embodiment of the present invention;

FIG. 10 is a set of cross-sectional views that show a step of a second embodiment of the fabrication of metal lines with a small tip-to-top spacing, where a cut region is etched into the conductive via and the adhesion layer to expose a top surface of the substrate, in accordance with an embodiment of the present invention;

FIG. 11 is a set of cross-sectional views that show a step of a second embodiment of the fabrication of metal lines with a small tip-to-top spacing, where additional conductive material is selectively deposited on sidewalls of the vias, in accordance with an embodiment of the present invention;

FIG. 12 is a set of cross-sectional views that show a step of a second embodiment of the fabrication of metal lines with a small tip-to-top spacing, where a dielectric material is deposited using a process that pinches off to create an air-gapped dielectric cut structure, in accordance with an embodiment of the present invention;

FIG. 13 is a block/flow diagram of a first embodiment of a method of fabricating metal lines with a small tip-to-tip spacing by selectively etching a multilayer dielectric plug, in accordance with an embodiment of the present invention; and

FIG. 14 is a block/flow diagram of a second embodiment of a method of fabricating metal lines with a small tip-to-tip structure by selectively depositing conductive material in a cut region, in accordance with an embodiment of the present invention.

### DETAILED DESCRIPTION

Forming interconnect lines with tip-to-tip spacing that is smaller than the pitch available with a given fabrication technology may be useful when fabricating complex semiconductor devices. For example, when layering perpendicular interconnects with a device pitch of less than 20 nm, a tip-to-tip spacing of less than 8 nm for the underlying interconnects may be used to improve contact surface area for vias to the overlying interconnects.

One approach to reducing the tip-to-tip spacing for interconnects is to form multi-layer interconnect cut structures before forming the interconnects themselves. These multi-layer interconnect cut structures may be formed using a minimum feature size of the fabrication technology, and then may be selectively etched to reduce their size, making it possible to create interconnects having a tip-to-tip spacing that is substantially smaller than the pitch that can be directly produced by the manufacturing technology.

Another approach to reducing the tip-to-tip spacing for interconnects is to etch an interconnect cut after formation of the interconnect, thereby forming a gap that cuts the conductive line into two interconnects. This initial interconnect cut may be formed with a minimum feature size of the fabrication technology. Additional interconnect material may then be selectively deposited in the interconnect cut to narrow the spacing between the interconnect tips to a width that is substantially smaller than the spacing that can be directly produced by the manufacturing technology.

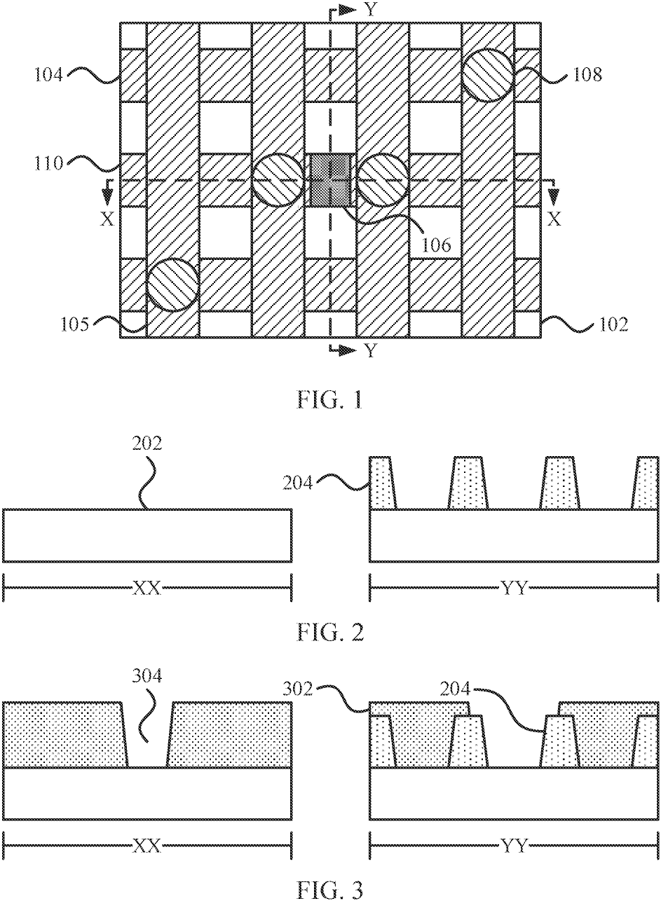

Referring now to FIG. 1, a top-down view of an interconnect layer in a semiconductor device is shown. A semiconductor substrate 102 is shown underneath the interconnect layer. Multiple layers of interconnects are shown, including a layer of first interconnects 104 and a layer of second interconnects 105. Between the layers of interconnects, filling the space that is illustrated, is an interlayer dielectric material (e.g., silicon dioxide) that electrically insulates the interconnects 104 from one another and from the substrate 102, as needed. The interlayer dielectric is omitted in this view, to help visualize the interconnect structures. Vias 108 connect the first interconnects 104 to the second interconnects 105. These vias are formed from conductive material that provides electrical communication between the layers.

An interconnect cut structure 106 is shown, cutting one of the first interconnects 104 into two parallel interconnects 110, positioned end-to-end with a gap between them. The size of the interconnect cut structure 106 defines a tip-to-tip spacing between the cut interconnects 110. As will be described in greater detail below, there are multiple ways to create such an interconnect cut structure 106. Notably, the interconnect cut structure 106 has a width that is smaller than the spacing between parallel interconnects 104.

This view defines two different cross-sectional planes: XX and YY. Each cross-sectional plane cuts through the interconnect cut structure 106. Series of steps are shown to illustrate how the interconnect cut structure 106 and the cut interconnects 110 may be formed.

Referring now to FIG. 2, a set of cross-sectional views are shown to illustrate a step in a first embodiment of the fabrication of interconnect structures. A trench pattern is formed on a substrate 202 by depositing a dielectric material on the substrate 202 and patterning the dielectric material, forming trench lines 204.

The substrate 202 may be a semiconductor substrate, which may include one or more device or interconnect layers. The substrate 202 may be a bulk-semiconductor substrate or may include any of a variety of devices formed or embedded within it, which may have electrical contacts at a surface of the substrate 202 to interface with conductive interconnects. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the substrate 202 may also be a semiconductor on insulator (SOI) substrate. The devices in and on the substrate may be any appropriate type of device, such as transistors, memories, optical devices, power devices, etc. Additional middle-of-line (MOL) or back-end-of-line (BEOL) interconnects may be formed over the devices.

The dielectric material of the trench lines 204 may include, for example, silicon dioxide or any other appropriate material, such as a low-k dielectric (e.g., a material with dielectric constant less than that of silicon dioxide). The material may be patterned by forming a photolithographic mask over the dielectric material, for example using a resist material that cures upon exposure to an applied light. After forming the photolithographic mask, exposed portions of the dielectric material may be selectively etched away using a reactive ion etch (RIE) process.

As used herein, the term “selective” in reference to a material removal process denotes that the rate of material removal for a first material is greater than the rate of removal for at least another material of the structure to which the material removal process is being applied. RIE is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface. Other examples of anisotropic etching that can be used at this point include ion beam etching, plasma etching or laser ablation. In this manner, the dielectric material may be removed to define the trench lines 204 without damaging the underlying substrate 202.

The dielectric material may be deposited using any appropriate deposition process including, e.g., chemical vapor deposition (CVD), physical vapor deposition (PVD), atomic layer deposition (ALD), or gas cluster ion beam (GCIB) deposition. CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use GCIB deposition, a high-pressure gas is allowed to expand in a vacuum, subsequently condensing into clusters. The clusters can be ionized and directed onto a surface, providing a highly anisotropic deposition.

Referring now to FIG. 3, a set of cross-sectional views are shown to illustrate a step in a first embodiment of the fabrication of interconnect structures. A layer of sacrificial planarizing material 302 is deposited over the trench lines and remaining dielectric 204. The planarizing material 302 may be patterned to form a cut region 304, which exposes the underlying substrate and sidewalls of a pair of dielectric lines. The width of the cut region 304 may be formed at a minimum feature size that a patterning process can achieve. For example, the width of the cut may be 14 nm using an extreme ultraviolet lithography and etch process. As will be described hereinbelow, this width can be decreased using additional processing steps to decrease the tip -to-tip spacing of the eventual conductive lines.

The sacrificial planarizing material 302 may be an organic planarizing layer (OPL). The OPL can be a self-planarizing organic material that includes carbon, hydrogen, oxygen, and optionally nitrogen, fluorine, and silicon. In one embodiment, the self-planarizing organic material can be a polymer with sufficiently low viscosity so that the top surface of the applied polymer forms a planar horizontal surface. In one embodiment, the OPL can include a transparent organic polymer. The OPL can be a CₓH_{y} polymer. The OPL can be applied, for example, by spin-coating.

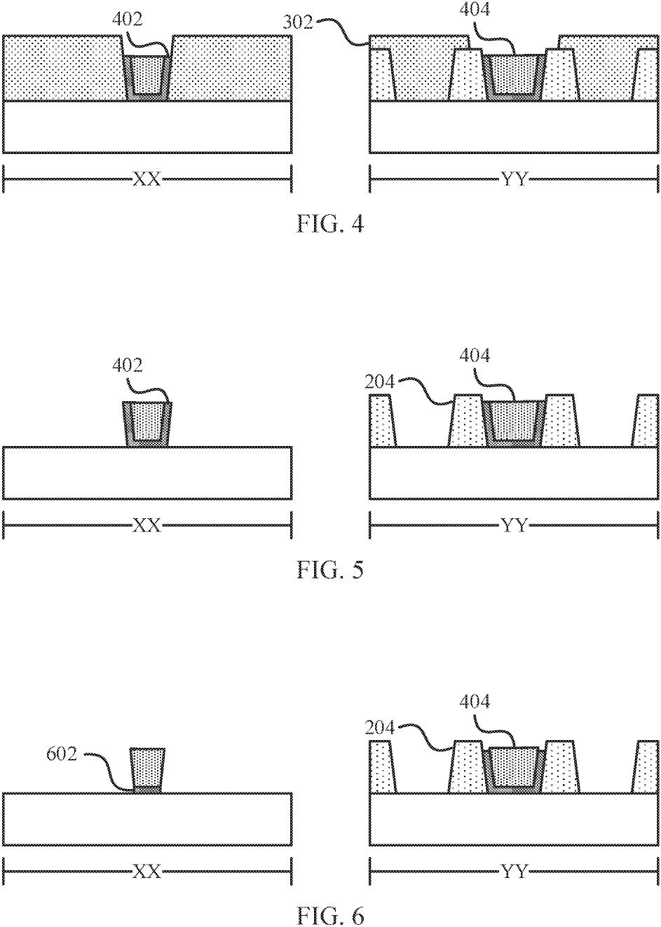

Referring now to FIG. 4, a set of cross-sectional views are shown to illustrate a step in a first embodiment of the fabrication of interconnect structures. A multilayer dielectric plug is formed, including a first dielectric layer 402 and a second dielectric layer 404. The first dielectric layer 402 may be formed by, e.g., conformally depositing a first dielectric material in the cut region 304, for example using a CVD or ALD process that coats the trench lines 204. The second dielectric layer 404 may be formed by depositing a second dielectric material over the first dielectric material, using any appropriate deposition process, such as CVD, PVD, or ALD, to fill the trench. After that, one or more selective etch processes may be applied to recess the second dielectric material and first dielectric material, such that top surface of the planarization material 302 is exposed.

The second dielectric material may be recessed relative to the first dielectric layer 402 using a selective etch that does not substantially damage the first dielectric layer 402. After that, first dielectric layer 402 may then be etched back using a selective etch that does not substantially damage the dielectric 204 and planarizing layer 302. The portions of the first dielectric layer 402 that are underneath the second dielectric layer 404 will be protected from this etch, so that the multilayer dielectric plug retains the first dielectric layer 402 on its sidewalls.

Any materials with appropriate etch selectivity may be used for the first dielectric layer 402 and the second dielectric layer 404, but it is specifically contemplated that the first dielectric layer 402 may be formed from silicon carbide and that the second dielectric layer 404 may be formed from, e.g., silicon nitride, aluminum oxide, or aluminum nitride.

Referring now to FIG. 5, a set of cross-sectional views are shown to illustrate a step in a first embodiment of the fabrication of interconnect structures. The planarizing layer 302 is removed, for example by ashing the organic material. This exposes the sidewalls of the multilayer dielectric plug, including the sidewalls of the first dielectric layer 402 in the trench, along the XX direction. The sidewalls of the multilayer plug along the YY direction are protected by the dielectric lines 204 and so the first dielectric layer 402 is not exposed on that surface.

Referring now to FIG. 6, a set of cross-sectional views are shown to illustrate a step in a first embodiment of the fabrication of interconnect structures. A selective isotropic etch, such as a wet or dry chemical etch, may be used to etch back the exposed portions of the first dielectric layer 402. The parts of the first dielectric layer 402 that are positioned between the second dielectric layer 404 and the trench lines 204 are protected from the etch. The protected portions of the first dielectric layer 402 form first dielectric remnants 602 underneath the second dielectric layer 404 and between the second dielectric layer 404 and the dielectric lines 204. Etching back the first dielectric layer 402 in the XX direction reduces the size of the multilayer dielectric plug in this direction. For example, if the first dielectric layer 402 has a thickness of about 3 nm, then a 14 nm cut can be reduced to about 8 nm.

Referring now to FIG. 7, a set of cross-sectional views are shown to illustrate a step in a first embodiment of the fabrication of interconnect structures. A layer of conductive material is deposited using any appropriate deposition process. The structures may then be polished down to at least the height of the first dielectric remnants 602 using a chemical mechanical planarization (CMP) process. This leaves conductive lines 704, which are separated by the multilayer dielectric plug 702. Thus, the tip-to-tip separation in the XX between the conductive lines 704 may be less than the original cut size.

CMP is performed using, e.g., a chemical or granular slurry and mechanical force to gradually remove upper layers of the device. The slurry may be formulated to be unable to dissolve, for example, the work function metal layer material, resulting in the CMP process’s inability to proceed any farther than that layer.

The conductive material may include, e.g., tungsten, nickel, titanium, molybdenum, tantalum, copper, platinum, silver, gold, ruthenium, iridium, rhenium, rhodium, cobalt, and alloys thereof. A thin adhesion layer, such as TiN or TaN, may be deposited prior to the conductive metal deposition. The conductive material may alternatively be formed from a doped semiconductor material such as, e.g., doped polysilicon. At this stage, another layer of interconnects can be formed over the conductive lines 704, for example with a layer of interlayer dielectric that may be pierced by conductive vias, which provide electrical communication between interconnects on different levels.

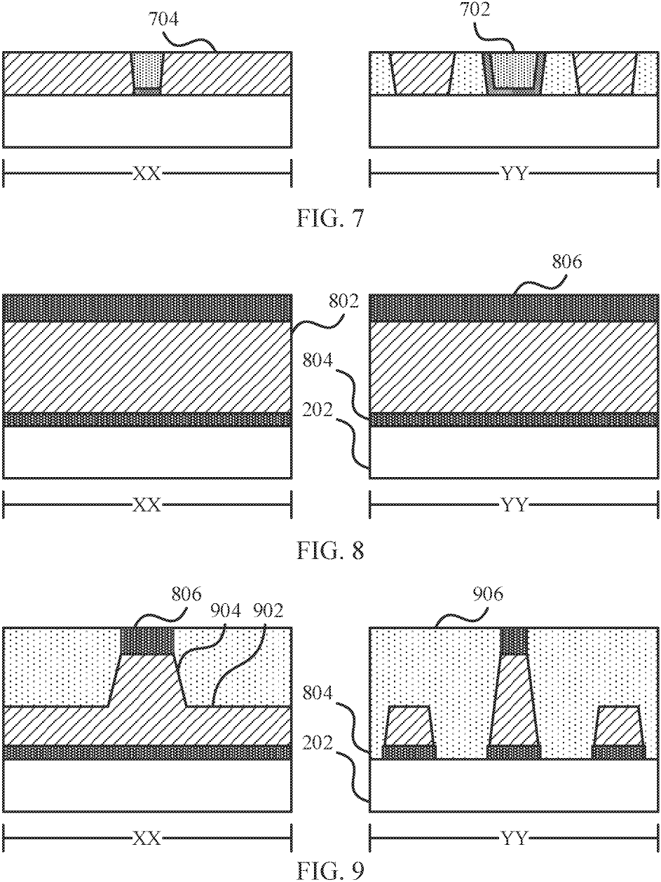

Referring now to FIG. 8, a set of cross-sectional views are shown to illustrate a step in a second embodiment of the fabrication of interconnect structures. This view shows the beginning of an alternative approach to the fabrication of interconnect structures with a small tip-to-tip distance. In this example, a layer of conductive material 802 is deposited over the substrate 202 by any appropriate deposition process. The substrate 202 may be any appropriate substrate, as described above. An adhesion layer 804 may be used to facilitate adhesion between the conductive material 802 and the substrate 202, and may be deposited on the substrate 202 using any appropriate deposition process, before formation of the conductive material 802. For an exemplary conductive material 802 that is formed from ruthenium, the adhesion layer 804 may be formed from, e.g., tantalum nitride. A hardmask layer 806 may be formed on the conductive material 802 using any appropriate process. The hardmask layer 806 may be formed from any appropriate material, such as silicon nitride.

Referring now to FIG. 9, a set of cross-sectional views are shown to illustrate a step in a second embodiment of the fabrication of interconnect structures. A hardmask may be formed to etch down into the conductive layer 802, for example using a photolithographic process. The hardmask is used to pattern the conductive layer 802 to form conductive lines 902, with a conductive via 904 on at least one of the conductive lines 902.

An interlayer dielectric 906 is deposited over the lines 902 and is polished down, for example using CMP, to expose top surfaces of the remaining portion of hardmask 908. The interlayer dielectric may be formed from any appropriate dielectric material, such as silicon dioxide. The formation of the conductive lines 902 and conductive vias 904 may be achieved by using subtractive metal patterning, for example by forming metal lines by lithography, followed by removal of metals that are not covered by hardmask. After that, another lithographic mask may be applied to cover the vias 904 and hardmasks and metal lines that are not covered by the remaining mask 908 are etched to form the recessed conductive lines 902.

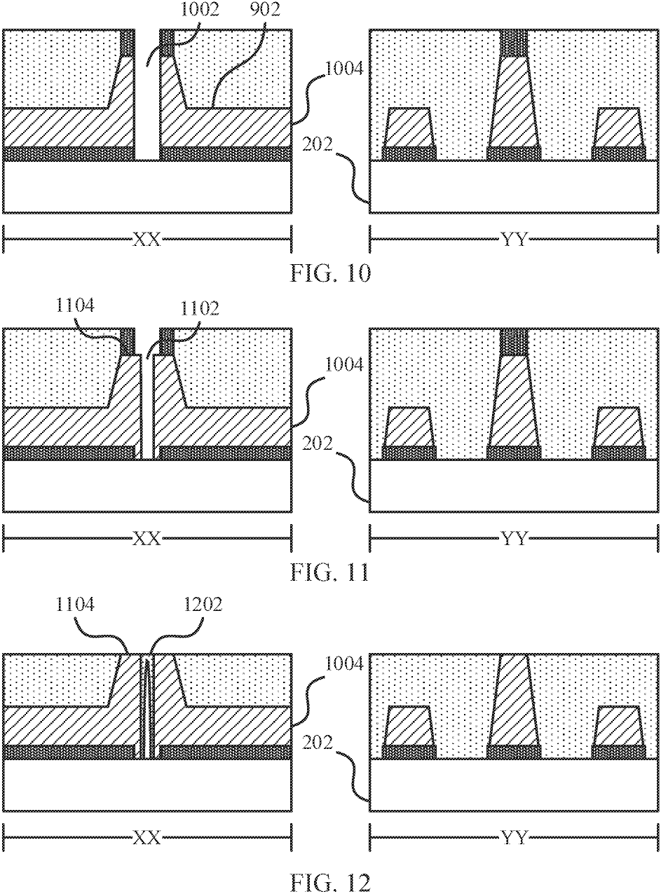

Referring now to FIG. 10, a set of cross-sectional views are shown to illustrate a step in a second embodiment of the fabrication of interconnect structures. A conductive line cut opening 1002 is etched through the via 904. The conductive line cut opening 1002 extends down to expose the top surface of the substrate 202, and may additionally penetrate the adhesion layer 804. This opening may be formed at the minimum size that can be achieved using the fabrication technology in question, and may cut the conductive line 902 into two distinct interconnect portions 1004 with the cut opening 1002.

Referring now to FIG. 11, a set of cross-sectional views are shown to illustrate a step in a second embodiment of the fabrication of interconnect structures. Additional conductive material is deposited on sidewalls of the conductive line cut opening 1002 using a selective deposition process, for example depositing additional metal on the metal of the conductive vias 904 and conductive lines 902, which shrinks the gap 1102 between the cut interconnects 1004.

The amount of additional conductive material that is selectively deposited may be controlled to produce a gap of any appropriate size. For example, by depositing about 3 nm of material, an original gap of about 14 nm may shrink to about 8 nm. This gap may define the tip-to-tip spacing of the cut conductive interconnects 1004.

Referring now to FIG. 12, a set of cross-sectional views are shown to illustrate a step in a second embodiment of the fabrication of interconnect structures. The gap 1102 between the cut interconnects 1004 is filled with a dielectric material using a non-conformal deposition process that pinches off at the opening of the gap 1102. This forms an air-gapped dielectric plug 1202, which electrically insulates the cut interconnects 1004 from one another. For example, the air-gapped dielectric plug 1202 may be formed from SiN, SiOCN, SiBCN, SiC, SiO₂, AlOₓ, AlNₓ, or an appropriate low-k dielectric. Excessive dielectric materials and hardmasks may be removed from the top surface of the interlayer dielectric 906 by CMP. At this stage, additional layers of interconnects may be formed over the interlayer dielectric 906, for example making electrical contact with the vias 1104.

The use of an air-gap lowers the effective dielectric constant of the dielectric plug 1202. Reduction of capacitance is of significant concern as fabrication technologies improve and device pitch continues to scale down. Stray capacitances in an integrated chip can limit the performance of the chip, particularly in high-frequency applications, and cause unwanted resonance with any inductances present in the chip. For example, a pair of adjacent conductive lines may be modeled as a parallel plate capacitor, with each conductive line being represented as one plate of the capacitor. The capacitance between the lines may therefore be expressed as:

$$C = \frac{k {ε}_{0} A}{d}$$

where A is the area of the plates, d is the distance between the plates, ε₀ is the permittivity of free space, and k is the dielectric constant of the material between the plates. The capacitance is therefore inversely proportional to the distance between the plates-as device size scales down and the pitch between lines decreases, the capacitance between the lines increases. However, capacitance is also proportional to the dielectric constant k. Thus, the use of air-gapped dielectric materials, with air having a dielectric constant of about one, can therefore substantially lower the capacitance between the interconnect tips.

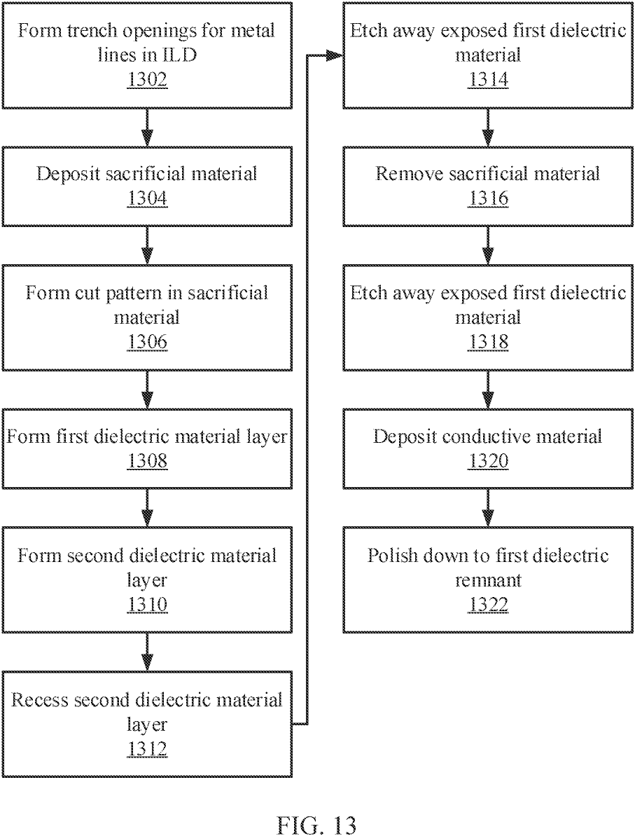

Referring now to FIG. 13, a first embodiment of method of forming interconnects with a small tip-to-tip separation is shown. Block 1302 forms dielectric lines 204 on a substrate 202, for example by depositing a dielectric material and then patterning the dielectric material using a photolithographic process. Block 1304 deposits a sacrificial material 302 over the dielectric lines 204, and block 1306 forms a cut pattern in the sacrificial material.

Block 1308 forms a first dielectric material using a conformal deposition process and block 1310 forms a second dielectric material, over the first dielectric material. Block 1312 then recesses the second dielectric material to a height below a height of the dielectric lines 204, thereby forming second dielectric material layer 404. Block 1314 etches away exposed portions of the first dielectric material, leaving behind first dielectric material layer 402. Block 1316 removes the sacrificial material 302, for example by ashing.

Block 1318 selectively etches away exposed first dielectric material, leaving first dielectric material remnants 602 in areas that are protected by the second dielectric layer 404. Block 1320 deposits conductive material, which fills the trenches between the dielectric lines 204. Block 1322 polishes down the conductive material and other layers, down to the level of the first dielectric material remnants 602. This produces cut interconnects 704.

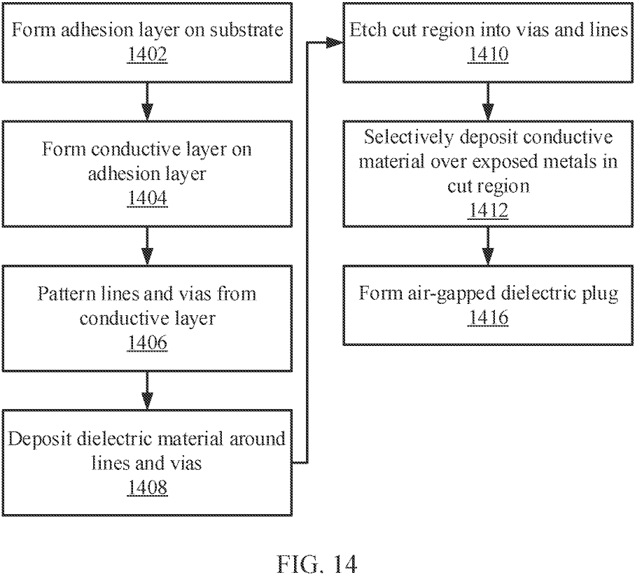

Referring now to FIG. 14, a second embodiment of a method of forming interconnects with a small tip-to-tip separation is shown. Block 1402 forms adhesion layer 804 on a substrate. Block 1404 then forms a conductive layer 802 on the adhesion layer 804 using any appropriate deposition process. Block 1406 patterns the conductive layer 802 to form conductive lines 902 and vias 904. Block 1408 deposits dielectric material around the lines 902 and vias 904, polishing down to expose the tops of the vias 904, thereby forming interlayer dielectric 906.

Block 1410 anisotropically etches cut region 1002 into the vias 904 and lines 902, thereby separating a line 902 into cut interconnects 1004. Block 1412 selectively deposits additional conductive material on exposed metals in the cut region, which narrows the cut region 1102. Block 1416 then forms an air-gapped dielectric plug 1202 in the narrowed cut region 1202.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element’s or feature’s relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of line formation with small tip spacing (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A method of forming lines, comprising:
forming a multilayer dielectric structure, including a first dielectric layer and a second dielectric layer, between dielectric lines;
etching away exposed portions of the first dielectric layer, leaving remnants between the second dielectric layer and the dielectric lines, to decrease a width of the multilayer dielectric structure; and
forming conductive lines between the dielectric lines, on respective sides of the multilayer dielectric structure.

2. The method of claim 1, wherein forming the multilayer dielectric structure includes:
conformally depositing a first dielectric material on a surface of the dielectric lines and an underlying substrate; and
depositing a second dielectric material on the first dielectric material to fill a space between the dielectric lines.

3. The method of claim 2, wherein forming the multilayer dielectric structure further comprises recessing the second dielectric material to a height below a height of the dielectric lines to form the second dielectric layer.

4. The method of claim 3, wherein forming the multilayer dielectric structure further comprises etching away portions of the first dielectric material that are exposed around the second dielectric layer.

5. The method of claim 1, wherein forming the conductive lines includes depositing conductive material between the dielectric lines, on respective sides of the multilayer dielectric structure, to a height greater than the multilayer dielectric structure.

6. The method of claim 5, wherein forming the conductive lines includes polishing a top surface of the conductive material down to at least a height of a top surface of the multilayer dielectric structure.

7. The method of claim 1, further comprising forming the dielectric lines using a fabrication process with a minimum pitch size, wherein the multilayer dielectric structure has a width that is smaller than the minimum pitch size after the multilayer dielectric structure has been etched to remove exposed portions of the first dielectric layer.

8. A method of forming lines, comprising:
patterning a conductive layer to form a conductive line on an underlying substrate;
etching a cut region into the conductive line to expose a surface of the underlying substrate and to cut the conductive line into respective interconnects;
selectively depositing additional conductive material on sidewalls of the cut region to decrease a width of the cut region; and
forming a dielectric plug in the cut region.

9. The method of claim 8, wherein patterning the conductive layer further forms a via structure on the conductive line.

10. The method of claim 9, wherein etching the cut region positions the cut region in the via structure, forming vias on the respective interconnects.

11. The method of claim 10, wherein selectively depositing additional conductive material further increases a top surface area of the vias on the respective interconnects.

12. The method of claim 8, further comprising:
depositing an adhesion layer before on the underlying substrate; and
depositing the conductive layer on the adhesion layer, wherein etching the cut region further etches the adhesion layer, such that the selective deposition of additional conductive material deposits material on the exposed surface of the underlying substrate.

13. The method of claim 8, wherein forming the dielectric plug uses a process and material that pinches off to create an air-gap in the dielectric plug.

14. A semiconductor device, comprising:
a pair of conductive interconnects, arranged end-to-end;
at least one conductive interconnect that is parallel to the pair of conductive interconnects, with a feature pitch separating the at least one conductive interconnect from the pair of conductive interconnects that is associated with a fabrication process; and
a dielectric structure between the pair of conductive interconnects, having a width that is smaller than the feature pitch.

15. The semiconductor device of claim 14, further comprising a dielectric line between the at least one conductive interconnect and the pair of conductive interconnects.

16. The semiconductor device of claim 15, wherein the dielectric structure includes a first dielectric layer that contacts a sidewall of the dielectric line and on a top surface of an underlying substrate.

17. The semiconductor device of claim 16, wherein the dielectric structure further includes a second dielectric layer formed on the first dielectric layer, and wherein the first dielectric layer is absent between the pair of conductive interconnects and the second dielectric layer.

18. The semiconductor device of claim 14, wherein the pair of conductive interconnects include respective conductive vias, and the dielectric structure passes directly between the respective vias.

19. The semiconductor device of claim 18, further comprising an adhesion layer positioned between the pair of conductive interconnects and an underlying substrate, wherein the dielectric structure pierces the adhesion layer to contact the underlying substrate and wherein the pair of conductive interconnects directly contact the underlying substrate in a region adjacent to the dielectric structure.

20. The semiconductor device of claim 18, wherein the dielectric structure includes an air gap.
